(19) United States
(12) Patent Application Publication
(10) Pub. No.: US 2025/0031548 A1
(43) Pub. Date: Jan. 23, 2025

(54) MOTHERBOARD FOR DISPLAY DEVICE AND METHOD OF MANUFACTURING DISPLAY DEVICE

(71) Applicant: Japan Display Inc., Tokyo (JP)

(72) Inventor: Hiroshi TABATAKE, Tokyo (JP)

(73) Assignee: Japan Display Inc., Tokyo (JP)

(21) Appl. No.: 18/773,746

(22) Filed: Jul. 16, 2024

(30) Foreign Application Priority Data
Jul. 19, 2023 (JP) 2023-117480

(51) Int. Cl. H10K 59/40; G09G 3/00; H10K 59/12; H10K 59/122; H10K 59/131; H10K 59/18; H10K 71/00; H10K 71/70

(52) U.S. Cl. CPC H10K 59/40; G09G 3/006; H10K 59/1201; H10K 59/122; H10K 59/131; H10K 59/18; H10K 71/70; H10K 71/851

(57) ABSTRACT

According to one embodiment, a motherboard includes inspection pads for adjacent short-circuiting inspection. The motherboard includes a first high-resistance wiring line connecting the inspection pads to each other, a first cut line set to cut out a plurality of display devices from the motherboard, and a second cut line set along an outline shape of each single display device. The inspection pads are each located between the first cut line and the second cut line. The first high-resistance wiring line is disposed across the first cut line and cut along the first cut line before the inspection using the inspection pads. The inspection pads are not connected to each other by the first high-resistance wiring line at the time of the inspection.

### CROSS-REFERENCE TO RELATED APPLICATION

This application is based upon and claims the benefit of priority from Japanese Patent Application No. 2023-117480, filed Jul. 19, 2023, the entire contents of which are incorporated herein by reference.

### FIELD

Embodiments described herein relate generally to a motherboard for display device, and a method of manufacturing a display device.

### BACKGROUND

Recently, display devices with organic light emitting diodes (OLED) applied as display elements have been put into practical use. This display element comprises a lower electrode, an organic layer covering the lower electrode, and an upper electrode covering the organic layer.

The display device may have in some cases a touch panel which detect the operation on the display area by the user. In manufacturing a display device with such a touch panel, it is necessary to inspect whether each adjacent pair of a plurality of electrodes which constitutes the touch panel are not short-circuited. This inspection is called adjacent short-circuiting inspection, and there is a need for technique that can improve the accuracy of this inspection.

### BRIEF DESCRIPTION OF THE DRAWINGS

FIG. 1 is a perspective view schematically showing a configuration example of a display device according to one embodiment.

FIG. 2 is a perspective view schematically showing a configuration example of a touch panel of the embodiment.

FIG. 3 is a cross-sectional view schematically showing a configuration example of the display device according to the embodiment.

FIG. 4 is a plan view schematically illustrating an example of a configuration of inspecting adjacent short-circuiting in a touch panel.

FIG. 5 is a plan view schematically illustrating an example of a configuration of inspecting adjacent short-circuiting in the touch panel of the embodiment.

FIG. 6 is a plan view schematically showing a motherboard for the display device according to the embodiment.

FIG. 7 is a cross-sectional view schematically showing the display device according to the embodiment.

### DETAILED DESCRIPTION

In general, according to one embodiment, a motherboard for display device, comprises a plurality of display devices are formed thereon, each comprising a display panel including a display area for displaying images and a touch panel including a plurality of touch electrodes overlapping the display area. The motherboard comprises a plurality of inspection pads each provided for each respective display device so as to inspect whether two touch electrodes adjacent to each other of the plurality of touch electrodes are short-circuited. The motherboard comprises a first high-resistance wiring line connecting the plurality of inspection pads to each other. The motherboard comprises a first cut line set to cut out a plurality of display devices from the motherboard for display device. The motherboard comprises a second cut line set along an outline shape of each single display device. The plurality of inspection pads are each located between the first cut line and the second cut line and are electrically connected to the corresponding touch electrode for the inspection. The first high-resistance wiring line is disposed across the first cut line and cut along the first cut line before the inspection using the plurality of inspection pads. The plurality of inspection pads are not connected to each other by the first high-resistance wiring line at the time of the inspection.

According to another embodiment, there is provided a method of manufacturing each single display device from a motherboard comprising a plurality of display devices formed thereon, each comprising a display panel including a display area for displaying images and a touch panel including a plurality of touch electrodes overlapping the display area, the motherboard comprising a first cut line, a second cut line, a plurality of inspection pads provided between the first cut line and the second cut line, each provided for each respective display device, and a first high-resistance wiring line connecting the plurality of inspection pads to each other. The method of manufacturing the display device comprises cutting out a plurality of display devices from the motherboard for display device by cutting the motherboard for display device along the first cut line set to cross the first high-resistance wiring line, inspecting whether two touch electrodes adjacent to each other among the plurality of touch electrodes are short-circuited using the plurality of inspection pads, and forming an outline shape of each single display device by cutting the plurality of display devices along the second cut line after the inspection.

Embodiments will be described hereinafter with reference to the accompanying drawings.

Note that the disclosure is merely an example and is not limited by contents described in the embodiments described below. Modification which is easily conceivable by a person of ordinary skill in the art comes within the scope of the disclosure as a matter of course. In order to make the description clearer, the sizes, shapes and the like of the respective parts may be changed and illustrated schematically in the drawings as compared with those in an accurate representation. Constituent elements corresponding to each other in a plurality of drawings are denoted by like reference numerals and their detailed descriptions may be omitted unless necessary.

In the figures, an X-axis, a Y-axis and a Z-axis orthogonal to each other are described to facilitate understanding as needed. A direction along the X-axis is referred to as a first direction, a direction along the Y-axis is referred to as a second direction, and a direction along the Z-axis is referred to as a third direction. The third direction Z is a normal to a plane including the first direction X and the second direction Y. In addition, viewing various elements parallel to the third direction Z is referred to as plan view.

The display device of this embodiment is an organic electroluminescent display device comprising an organic light emitting diode (OLED) as a display element, and can be mounted on various electronic devices such as televisions, personal computers, in-vehicle devices, tablet terminals, smartphones, mobile phones, and wearable terminals. Further, the display device of this embodiment is a display device with a touch panel that can detect operations on the display area by the user.

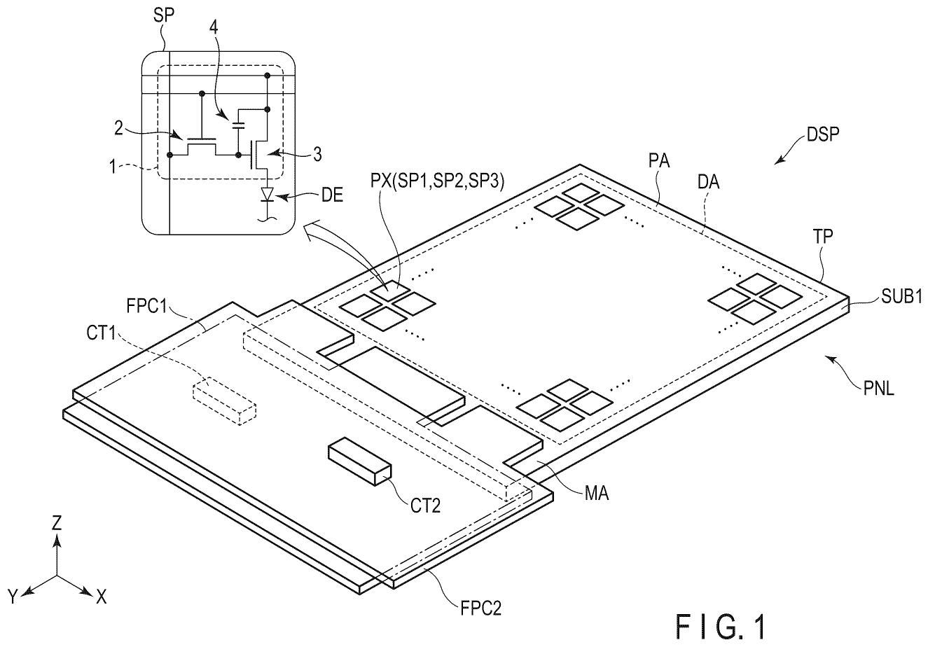

FIG. 1 is a perspective view schematically showing a configuration example of a display device DSP according to the embodiment. The display device DSP comprises a display panel PNL, a touch panel TP, a first wiring board FPC1, and a second wiring board FPC2. The display panel PNL comprises a first substrate SUB1. The display panel PNL includes a display area DA that displays images and a peripheral area PA surrounding the display area DA.

The display panel PNL includes a plurality of pixels PX arranged in a matrix along the first direction X and the second direction Y in the display area DA. The pixels PX each contain a plurality of subpixels SP. For example, the pixels PX each contain a red subpixel SP1, a green subpixel SP2, and a blue subpixel SP3. The pixel PX may as well contain a subpixel SP of another color, such as white, together with or instead of any of the subpixels SP1, SP2, and SP3.

The subpixels SP each comprise a pixel circuit 1 and a display element DE driven by the pixel circuit 1. The pixel circuit 1 comprises a pixel switch 2, a drive transistor 3, and a capacitor 4. The pixel switch 2 and the drive transistor 3 are switching elements each constituted by a thin-film transistor, for example.

The gate electrode of the pixel switch 2 is connected to a respective scanning line GL. One of the source and drain electrodes of the pixel switch 2 is connected to a respective signal line SL, and the other is connected to the gate electrode of the drive transistor 3 and the capacitor 4. In the drive transistor 3, one of the source and drain electrodes is connected to a respective power line PL and the capacitor 4, and the other is connected to the display element DE.

The configuration of the pixel circuit 1 is not limited to that of the example shown in the figure. For example, the pixel circuit 1 may as well comprise more thin-film transistors and capacitors.

The first substrate SUB1 includes a mounting area MA. In the mounting area MA, the first wiring board FPC1 and the second wiring board FPC2 are disposed. The first circuit board FPC1 includes a display controller CT1 that executes control related to image display, provided thereon.

The touch panel TP is provided to overlap the display area DA of the display panel PNL. As will be described in detail later, the touch panel TP includes a plurality of touch electrodes. These touch electrodes are electrically connected to the second wiring board FPC2. The second wiring board FPC2 includes a detection controller CT2 that executes control related to touch detection, provided therein.

The display controller CT1 and the detection controller CT2 are each constituted by an IC, for example. Note that FIG. 1 shows a configuration in which the display controller CT1 and the detection controller CT2 are mounted on separate circuit boards, respectively, but these controllers CT1 and CT2 may as well be mounted on the same circuit board.

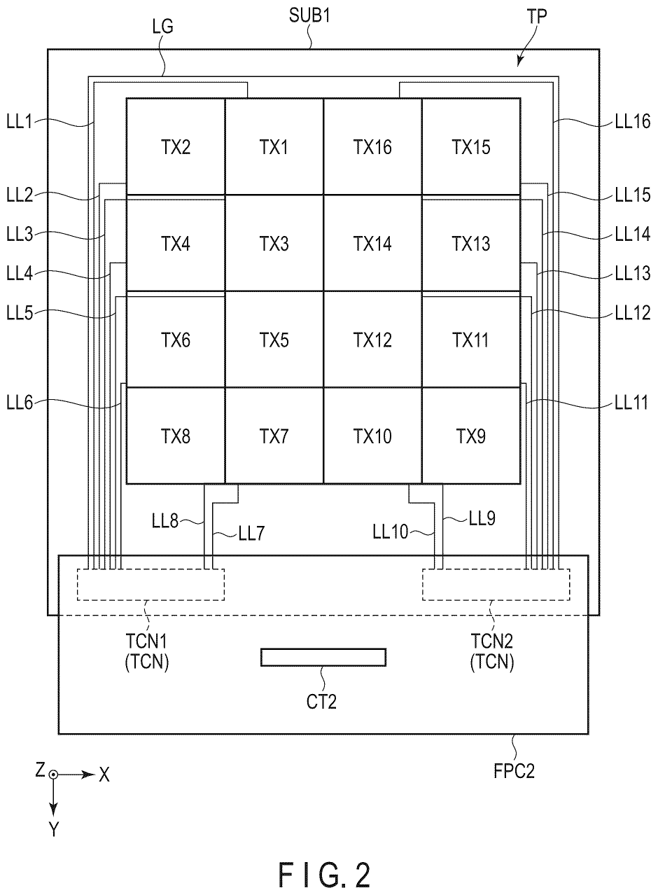

FIG. 2 is a plan view schematically showing an example of the configuration of the touch panel TP of the embodiment. As shown in FIG. 2, the touch panel TP includes a plurality of touch electrodes TX. In the example of FIG. 2, sixteen (four rows×four columns) touch electrodes TX1 to TX16 are arranged in a matrix. Of the touch electrodes TX1 to TX16, the touch electrodes TX1 to TX8 are located in the left half of the figure, and the touch electrodes TX9 to TX16 are located in the right half.

As shown in FIG. 2, the touch electrode TX1 is disposed adjacent to the touch electrodes TX2 and TX16 along the first direction X. The touch electrode TX1 is disposed adjacent to the touch electrode TX3 along the second direction Y.

The touch electrode TX2 is disposed adjacent to the touch electrode TX1 along the first direction X. The touch electrode TX2 is disposed adjacent to the touch electrode TX4 along the second direction Y.

The touch electrode TX3 is disposed adjacent to the touch electrodes TX4 and TX14 along the first direction X. The touch electrode TX3 is disposed adjacent to the touch electrodes TX1 and TX5 along the second direction Y.

The touch electrode TX4 is disposed adjacent to the touch electrode TX3 along the first direction X. The touch electrode TX4 is disposed adjacent to the touch electrodes TX2 and TX6 along the second direction Y.

The touch electrode TX5 is disposed adjacent to the touch electrodes TX6 and TX12 along the first direction X. The touch electrode TX5 is disposed adjacent to the touch electrodes TX3 and TX7 along the second direction Y.

The touch electrode TX6 is disposed adjacent to the touch electrode TX5 along the first direction X. The touch electrode TX6 is disposed adjacent to the touch electrodes TX4 and TX8 along the second direction Y.

The touch electrode TX7 is disposed adjacent to the touch electrodes TX8 and TX10 along the first direction X. The touch electrode TX7 is disposed adjacent to the touch electrode TX5 along the second direction Y.

The touch electrode TX8 is disposed adjacent to the touch electrode TX7 along the first direction X. The touch electrode TX8 is disposed adjacent to the touch electrode TX6 along the second direction Y.

The touch electrode TX9 is disposed adjacent to the touch electrode TX10 along the first direction X. The touch electrode TX9 is disposed adjacent to the touch electrode TX11 along the second direction Y.

The touch electrode TX10 is disposed adjacent to the touch electrodes TX7 and TX9 along the first direction X. The touch electrode TX10 is disposed adjacent to the touch electrode TX12 along the second direction Y.

The touch electrode TX11 is disposed adjacent to the touch electrode TX12 along the first direction X. The touch electrode TX11 is disposed adjacent to the touch electrodes TX9 and TX13 along the second direction Y.

The touch electrode TX12 is disposed adjacent to the touch electrodes TX5 and TX11 along the first direction X. The touch electrode TX12 is disposed adjacent to the touch electrodes TX10 and TX14 along the second direction Y.

The touch electrode TX13 is disposed adjacent to the touch electrode TX14 along the first direction X. The touch electrode TX13 is disposed adjacent to the touch electrodes TX11 and TX15 along the second direction Y.

The touch electrode TX14 is disposed adjacent to the touch electrodes TX3 and TX13 along the first direction X. The touch electrode TX14 is disposed adjacent to the touch electrodes TX12 and TX16 along the second direction Y.

The touch electrode TX15 is disposed adjacent to the touch electrode TX16 along the first direction X. The touch electrode TX15 is disposed adjacent to the touch electrode TX13 along the second direction Y.

The touch electrode TX16 is disposed adjacent to the touch electrodes TX1 and TX15 along the first direction X. The touch electrode TX16 is disposed adjacent to the touch electrode TX14 along the second direction Y.

The number and arrangement of touch electrodes TX are not limited to those of this example.

Lead lines LL1 to LL16 are connected to the touch electrodes TX1 to TX16, respectively. The lead lines LLI to LL16 are electrically connected to the second circuit board FPC2 (detection controller CT2) via connection portions TCN. More specifically, lead lines LL1 to LL8 are electrically connected to the second circuit board FPC2 via a connection portion TCN1, and the lead lines LL9 to LL16 are electrically connected to the second circuit board FPC2 via a connection portion TCN2.

For example, the touch electrodes TX1 to TX8, the lead lines LL1 to LL8 and the connection portion TCN1, and the touch electrodes TX9 to TX16, the lead lines LL9 to LL16 and the connection portion TCN2 are located in a line-symmetry shape with respect to the center line in the first direction X.

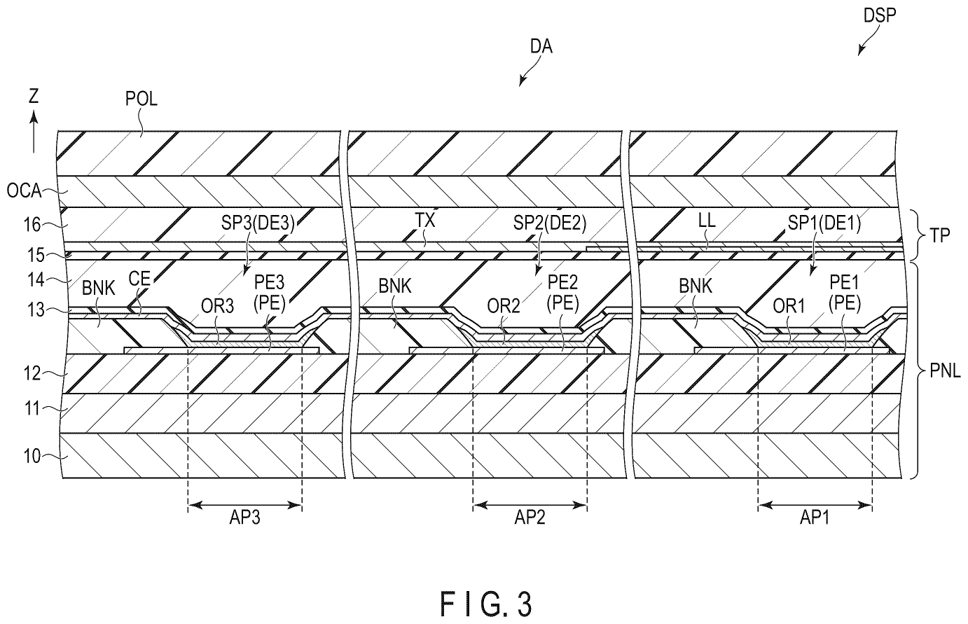

FIG. 3 is a cross-sectional view schematically showing an example of the configuration of the display device DSP. As shown in FIG. 3, the display device DSP includes an insulating substrate 10. The substrate 10 may be glass or a flexible resin film. On the substrate 10, a circuit layer 11 is disposed. The circuit layer 11 includes various types circuits and wiring lines, such as the pixel circuits 1, scanning lines GL, signal lines SL, power lines PL and the like shown in FIG. 1.

The circuit layer 11 is covered by an organic insulating layer 12. The organic insulating layer 12 functions as a planarization film to planarize the unevenness caused by the circuit layer 11. On the organic insulating layer 12, pixel electrodes PE1, PE2, and PE3 are disposed. Although not shown in the cross section of FIG. 3, the pixel electrodes PE1, PE2, and PE3 are each connected to the pixel circuit 1 included in the circuit layer 11 via contact holes formed in the organic insulating layer 12.

On the organic insulating layer 12 and the pixel electrodes PE1, PE2, PE3, a bank BNK is disposed. The bank BNK includes a pixel aperture AP1 to expose a part of the pixel electrode PE1, a pixel aperture AP2 to expose a part of the pixel electrode PE2, and a pixel aperture AP3 to expose a part of the pixel electrode PE3. The end portions of the pixel electrodes PE1, PE2, and PE3 are covered by the bank BNK.

On the pixel electrode PE1, an organic layer OR1 is disposed. The organic layer OR1 covers the pixel electrode PE1 through the pixel aperture AP1. On the pixel electrode PE2, an organic layer OR2 is disposed. The organic layer OR2 covers the pixel electrode PE2 via the pixel aperture AP2. On the pixel electrode PE3, an organic layer OR3 is disposed. The organic layer OR3 covers the pixel electrode PE3 via the pixel aperture AP3.

On the bank BNK and the organic layers OR1, OR2, and OR3, a common electrode CE is disposed. The common electrode CE is disposed over a plurality of pixels PX (subpixels SP) so as to oppose the pixel electrodes PE1, PE2, and PE3.

The portions of the pixel electrode PE1, the organic layer OR1 and the common electrode CE, which overlap the pixel aperture AP1 constitute a display element DE1 of the subpixel SP1. The portions of the pixel electrode PE2, the organic layer OR2, and the common electrode CE, which overlap the pixel aperture AP2 constitutes a display element DE2 of the subpixel SP2. The portions of the pixel electrode PE3, the organic layer OR3 and the common electrode CE, which overlap the pixel aperture AP3 constitute a display element DE3 of the subpixel SP3.

Note that the pixel electrodes PE1, PE2, and PE3 may as well be referred to as lower electrodes and the common electrode CE may be referred to as an upper electrode.

The common electrode CE is covered by a sealing layer 13. The sealing layer 13 is covered by a resin layer 14. The resin layer 14 is covered by a sealing layer 15. On the sealing layer 15, a touch electrode TX and a lead line LL connected to the touch electrode TX are disposed. The touch electrode TX and the lead line LL are formed by the same manufacturing process using the same material.

The touch electrode TX is covered by a resin layer 16. On the resin layer 16, an optical adhesive OCA is disposed. The optical adhesive OCA adheres the resin layer 16 and a polarizer POL disposed thereon, to each other.

The organic insulating layer 12 is formed of an organic insulating material. The bank BNK and the resin layers 14 and 16 are each formed of a resin material (organic insulating material) such as epoxy resin or acrylic resin. The sealing layers 13 and 15 are each formed of an inorganic insulating material such as silicon nitride (SiNx), silicon oxide (SiOx), silicon oxynitride (SiON), aluminum oxide (Al₂O₃) or the like.

The pixel electrodes PE1, PE2, PE3 each include a reflective layer formed of silver (Ag), for example, and a pair of conductive oxide layers that cover upper and lower surfaces of the reflective layer, respectively. Each of the conductive oxide layers can be made of, for example, indium tin oxide (ITO), indium zinc oxide (IZO), indium gallium zinc oxide (IGZO) or the like.

The organic layers OR1, OR2 and OR3 each have a stacked structure of, for example, a hole injection layer, a hole transport layer, an electron blocking layer, an emission layer, a hole blocking layer, an electron transport layer and an electron injection layer. The organic layers OR1, OR2, and OR3 may have the so-called tandem structure including a plurality of emission layers.

The common electrode CE is formed, for example, of a metallic material such as an alloy of magnesium and silver (MgAg).

A pixel voltage is supplied to the pixel electrodes PE1, PE2, and PE3 via the pixel circuit 1 of each of the subpixels SP1, SP2, and SP3. A common voltage is supplied to the common electrode CE.

The organic layers OR1, OR2, and OR3 emit light in response to the application of the voltage. For example, when a potential difference is created between the pixel electrode PE1 and the common electrode CE, the light-emitting layer of the organic layer OR1 emits light in a red wavelength range. When a potential difference is created between the pixel electrode PE2 and the common electrode CE, the light-emitting layer of the organic layer OR2 emits light in a green wavelength range. When a potential difference is created between the pixel electrode PE3 and the common electrode CE, the light-emitting layer of the organic layer OR3 emits light in a blue wavelength range.

As another example, the light-emitting layers of the organic layers OR1, OR2, and OR3 may emit light of the same color (for example, white). In this case, the display device DSP may comprise color filters that convert the light emitted by the light-emitting layers into light of colors corresponding to the subpixels SP1, SP2, and SP3, respectively. Further, the display device DSP may as well comprise a layer containing quantum dots that are excited by the light emitted by the light-emitting layer to generate light of colors corresponding to the subpixels SP1, SP2, and SP3, respectively.

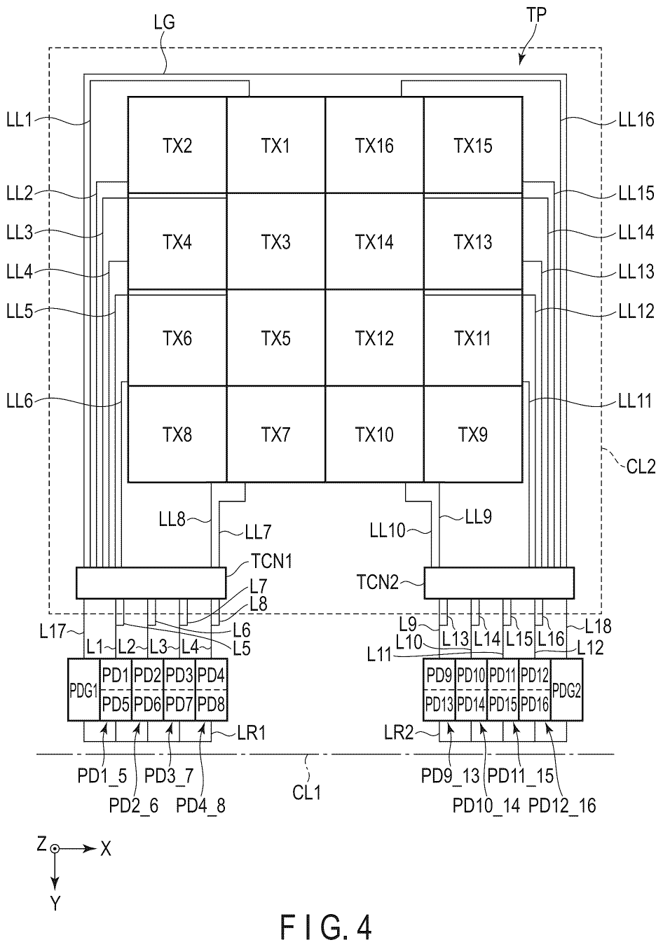

In manufacturing of the display device DSP with the touch panel TP as shown in FIGS. 1 to 3, it is necessary to inspect whether two touch electrodes TX adjacent to each other are not short-circuited. This inspection is referred to as the adjacent short-circuiting inspection and can be performed, for example, using the configuration shown in FIG. 4.

FIG. 4 is a plan view to illustrate an example of a configuration for inspecting adjacent short-circuiting in the touch panel TP.

The lead lines LL1 to LL8 drawn out from the touch electrodes TX1 to TX8, respectively, are connected to the connection portion TCN1 located in the mounting area MA. Further, as shown in FIG. 4, to connection portion TCN1, wiring lines L1 to L8 electrically connected to the touch electrodes TX1 to TX8 via the lead lines LLI to LL8, respectively, which as well are connected to inspection pads PD1 to PD8, respectively, are connected. Furthermore, to the connection portion TCN1, as shown in FIG. 4, an annular ground wiring line LG and a wiring line L17 electrically connected to the ground wiring line LG, which as well are connected to a ground pad PDG1 are connected.

As shown in FIG. 4, the inspection pad PD1 corresponding to the touch electrode TX1 and the inspection pad PD5 corresponding to the touch electrode TX5 are formed to be integrated as one body as one inspection pad PD1_5. Further, the wiring line L1 electrically connected to the touch electrode TX1 and the wiring line L5 electrically connected to the touch electrode TX5 are bundled together and connected to the inspection pad PD1_5. In this manner, a plurality of inspection pads PD corresponding to a plurality of touch electrodes TX which are not adjacent to each other are formed to be integrated as one body, and a plurality of wiring lines L electrically connected to these touch electrodes TX are bundled together and connected to the inspection pads PD. With this configuration, adjacent short-circuiting in the touch panel TP is not overlooked. Therefore, the number of inspection pads PD required for the inspection can be reduced. Here, the time required for adjacent short-circuiting inspection increases in proportion to the number of inspection pads PD. Therefore, the time required for adjacent short-circuiting inspection can be reduced by reducing the number of inspection pads PD.

Similarly, the inspection pad PD2 corresponding to the touch electrode TX2 and the inspection pad PD6 corresponding to the touch electrode TX6 are formed to be integrated as one body as one inspection pad PD2_6. The wiring line L2 electrically connected to the touch electrode TX2 and the wiring line L6 electrically connected to the touch electrode TX6 are bundled together and connected to the inspection pad PD2_6.

The inspection pad PD3 corresponding to the touch electrode TX3 and the inspection pad PD7 corresponding to the touch electrode TX7 are formed to be integrated as one body as one inspection pad PD3_7. The wiring line L3 electrically connected to the touch electrode TX3 and the wiring line L7 electrically connected to the touch electrode TX7 are bundled together and connected to the inspection pad PD3_7.

The inspection pad PD4 corresponding to the touch electrode TX4 and the inspection pad PD8 corresponding to the touch electrode TX8 are formed to be integrated as one body as one inspection pad PD4_8. The wiring line L4 electrically connected to the touch electrode TX4 and the wiring line L8 electrically connected to the touch electrode TX8 are bundled together and connected to the inspection pad PD4_8.

The inspection pads PD1_5, PD2_6, PD3_7, and PD4_8 and the ground pad PDG1 are connected to each other by an annular high-resistance wiring line LR1 (first high-resistance wiring line) referred to as a short-circuiting ring. With such an annular high-resistance wiring line LR1 thus provided, it is possible to prevent the display device DSP (display panel PNL) from being destroyed by static electricity caused by exfoliation charging, which occurs, for example, in the process of manufacturing the display device DSP (display panel PNL).

In the above-provided descriptions, the configuration of the left half of the figure is described, but a similar description can be applied to the configuration of the right half of the figure as well.

In more detail, the lead lines LL9 to LL16 drawn out from the touch electrodes TX9 to TX16, respectively, are connected to a connection portion TCN2 disposed in the mounting area MA. Further, as shown in FIG. 4, to the connection portion TCN2, the wiring lines L9 to L16 electrically connected to the touch electrodes TX9 to TX16 via the lead lines LL9 to LL16, respectively, which are connected to the inspection pads PD9 to PD16, respectively, are connected. Furthermore, as shown in FIG. 4, to the connection portion TCN2, a ring-shaped ground wiring line LG and the wiring line L18 electrically connected to the ground wiring line LG, which is connected to a ground pad PDG2 is connected.

The inspection pad PD9 corresponding to the touch electrode TX9 and the inspection pad PD13 corresponding to the touch electrode TX13 are formed to be integrated as one body as one inspection pad PD9_13. The wiring line L9 electrically connected to the touch electrode TX9 and the wiring line L13 electrically connected to the touch electrode TX13 are bundled together and connected to the inspection pad PD9_13.

The inspection pad PD10 corresponding to the touch electrode TX10 and the inspection pad PD14 corresponding to the touch electrode TX14 are formed to be integrated as one body as one inspection pad PD10_14. The wiring line L10 electrically connected to the touch electrode TX10 and the wiring line L14 electrically connected to the touch electrode TX14 are bundled together and connected to the inspection pad PD10_14.

The inspection pad PD11 corresponding to the touch electrode TX11 and the inspection pad PD15 corresponding to the touch electrode TX15 are formed to be integrated as one body as one inspection pad PD11_15. The wiring line L11 electrically connected to the touch electrode TX11 and the wiring line L15 electrically connected to the touch electrode TX15 are bundled together and connected to the inspection pad PD11_15.

The inspection pad PD12 corresponding to the touch electrode TX12 and the inspection pad PD16 corresponding to the touch electrode TX16 are formed to be integrated as one body as one inspection pad PD12_16. The wiring line L12 electrically connected to the touch electrode TX12 and the wiring line L16 electrically connected to the touch electrode TX16 are bundled together and connected to the inspection pad PD12_16.

The inspection pads PD9_13, PD10_14, PD11_15, PD12_16 and the ground pad PDG2 are connected to each other by a circular high-resistance wiring line LR2 (first high-resistance wiring) provided for measures to prevent static electricity.

Note that, as shown in FIG. 4, the inspection pads PD1_5, PD2_6, PD3_7, PD4_8, PD9_13, PD10_14, PD11_15, PD12_16, the ground pads PDG1 and PDG2, and the high-resistance wiring lines LR1 and LR2 are each located between a first cut line CL1 and a second cut line CL2. The first cut line CL1 is a cutting line set to cut out a plurality of display device DSPs from a motherboard for display devices, on which a plurality of display devices DSP are formed. The second cut line CL2 is a cutting line set along the external shape of a single display device DSP.

The adjacent short-circuiting inspection is carried out (performed) after cutting a motherboard for display devices along the first cut line CL1 and cutting out a plurality of display devices DSP from the motherboard for display devices. After the adjacent short-circuiting inspection in the touch panel TP is completed, display devices DSP are cut along the second cut line CL2 and their shapes are straightened into the outline of the final product. In other words, the inspection pads PD1_5, PD2_6, PD3_7, PD4_8, PD9_13, PD10_14, PD11_15, and PD12_16, the ground pads PDG1 and PDG2 and the high-resistance wiring lines LR1 and LR2, located between the first cut line CL1 and the second cut line CL2, are all detached from the display device DSP and do not remain in the final product. With this configuration, there is no need to provide a space in the display device DSP for the inspection pads PD, ground pads PDG, and high-resistance wiring lines LR for anti-static measures, and therefore it is possible to realize a narrower frame of the display device DSP.

However, the configuration shown in FIG. 4 entails the following drawbacks.

Let us suppose here that, for example, a voltage V1 is applied to inspect the pad PD1_5 and a voltage V2 (≠V1) is applied to the inspection pad PD2_6 in order to inspect the adjacent short-circuiting between the touch electrodes TX1 and TX2 and between the touch electrodes TX5 and TX6. As a result, when a predetermined resistance value is detected between the inspection pads PD1_5 and PD2_6, it is judged that a short-circuiting is detected between the touch electrodes TX1 and TX2 or between the touch electrodes TX5 and TX6 as a resistance value that should not normally be detected are detected. However, in the configuration shown in FIG. 4, the inspection pads PD1_5 and PD2_6 are connected to each other by the high-resistance wiring line LR1, which is provided as anti-static measures described above. Therefore, the resistance value, depending on its detected value, cannot be definitely determined as to whether the resistance value is caused by the short-circuiting between the touch electrodes TX1 and TX2 or between the touch electrodes TX5 and TX6, or it is due to the high-resistance wiring line LR1. In other words, it may not be possible to accurately detect the adjacent short-circuiting in the touch panel TP.

The configuration shown in FIG. 4 further entails the following drawbacks in the inspection other than the adjacent short-circuiting inspection described above.

For example, the continuity inspection of the annular ground wiring line LG is carried out (performed) by bringing probes into contact with the ground pads PDG1 and PDG2. However, in some cases, the probes to be brought into contact with the ground pads PDG1 and PDG2 may be misaligned and at least one of the probes may not be brought into contact the ground pad PDG1 or PDG2. In this case, the ground pad PDG1 and PDG2 are not electrically connected to each other, and an infinite resistance value is detected as a result of the continuity inspection. On the other hand, when the ground wiring line LG is disconnected, the ground pads PDG1 and PDG2 are not electrically connected to each other, and an infinite resistance value is detected as a result of the continuity inspection. That is, in the configuration shown in FIG. 4, when an infinite resistance value is detected in the continuity inspection of the annular ground wiring line LG, it is not possible to determine whether the resistance value is caused by a contact error of a probe or by disconnection of the ground wiring line LG.

For this reason, when an infinite resistance value is detected as a result of the continuity inspection of the circular ground wiring line LG, a plurality of attempts are made to bring the probes into contact with the ground pads PDG1 and PDG2. Then, if an infinite resistance value is detected in all of these attempts, it is detected as the disconnection of the ground wiring line LG. This method, however, requires multiple trials to determine whether the infinite resistance value detected as a result of the continuity inspection is caused by a contact error of a probe or by disconnection of the ground wiring line LG, thus causing the drawback of requiring time and labor.

Under these circumstances, in this embodiment, a configuration that can solve the above-described various drawbacks discussed above is described.

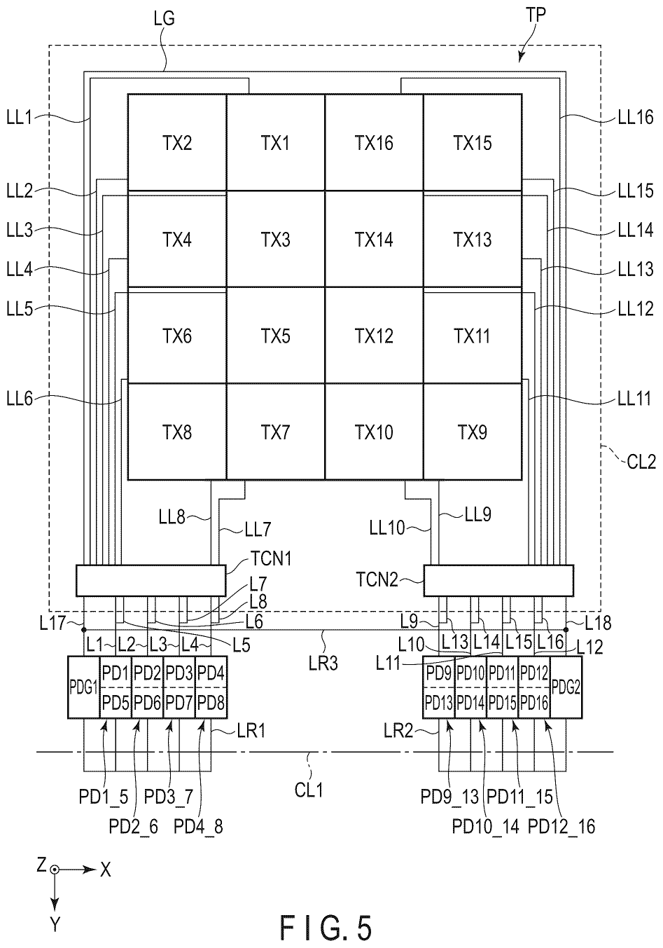

FIG. 5 is a plan view of an example of a configuration for inspecting the adjacent short-circuiting in the touch panel TP of this embodiment.

The configuration of this embodiment shown in FIG. 5 is different from the configuration of FIG. 4 in that the high-resistance wiring line LR1 that connects the inspection pads PD1_5, PD2_6, PD3_7, and PD4_8 and the ground pad PDG1 to each other, and the high-resistance wiring line LR2 that connects the inspection pads PD9_13, PD10_14, PD11_15, and PD12_16 and the ground pad PDG2 to each other are provided across the first cut line CL1. In other words, the configuration differs from that shown in FIG. 4 in that the first cut line CL1 is set to cross the high-resistance wiring lines LR1 and LR2.

Further, as shown in FIG. 5, this configuration is different from that shown in FIG. 4 in that the high-resistance wiring line LR3 (second high-resistance wiring line) that electrically connects the ground wiring line LG and the ground pads PDG1 and PDG2 is provided between the first cut line CL1 and the second cut line CL2. Note that the resistance value of the high-resistance wiring line LR3 should desirably higher than that of the ground wiring line LG, and preferably, the difference should be two digits or more. For example, when the resistance value of the ground wiring line LG is 3 kΩ, the resistance value of the high-resistance wiring line LR3 should be 300 kΩ or the like.

As described above, the adjacent short-circuiting inspection is carried out (performed) after cutting the motherboard for display devices along the first cut line CL1 and cutting out a plurality of display devices DSP from the motherboard for the display devices. Therefore, in the configuration shown in FIG. 5, the high-resistance wiring line LR1 is cut along the first cut line CL1 before the adjacent short-circuiting inspection, and the inspection pads PD1_5, PD2_6, PD3_7, PD4_8 and the ground pad PDG1 are not connected to each other by the high-resistance wiring line LR1 when inspecting the adjacent short-circuiting. Similarly, the high-resistance wiring line LR2 as well is cut along the first cut line CL1 before the adjacent short-circuiting inspection, and the inspection pads PD9_13, PD10_14, PD11_15, and PD12_16 and the ground pad PDG2 are not connected to each other by the high-resistance wiring line LR2 when inspecting the adjacent short-circuiting. With this configuration, while preventing the display panel PNL from being destroyed by static electricity generated in the process of manufacturing the display panel PNL by the high-resistance wiring lines LR1 and LR2, it is further possible to prevent the resistance values of the high-resistance wiring lines LR1 and LR2 from being detected in the adjacent short-circuiting inspection. In other words, the adjacent short-circuiting in the touch panel TP can be accurately detected.

Further, in the configuration shown in FIG. 5, as in the case of the configuration of FIG. 4, in the continuity inspection of the annular ground wiring line LG, when the probes to be brought into contact with the ground pads PDG1 and PDG2 are misaligned and at least one of the probes is not brought into contact with the ground pad PDG1 or PDG2, an infinite resistance value is detected as a result of the continuity inspection. On the other hand, in the configuration shown in FIG. 5, when the ground wiring line LG is disconnected, the resistance value of the high-resistance wiring line LR3 is detected as a result of the continuity inspection described above. Note that when there is no contact error between the ground pads PDG1 and PDG2 and the probes, and the ground wiring line LG is not disconnected, a composite resistance value of the resistance of the ground wiring line LG and the resistance of the high-resistance wiring line LR3 is detected as the result of the continuity inspection described above. With this configuration, it is possible to determine whether the ground wiring line LG is disconnected or whether there is a contact error between the ground pads PDG1 and PDG2 and the probe by a single continuity inspection (and further to determine that the ground wiring line LG is not disconnected). Therefore, the time and labor required for continuity inspection can be reduced as compared to those for the configuration shown in FIG. 4.

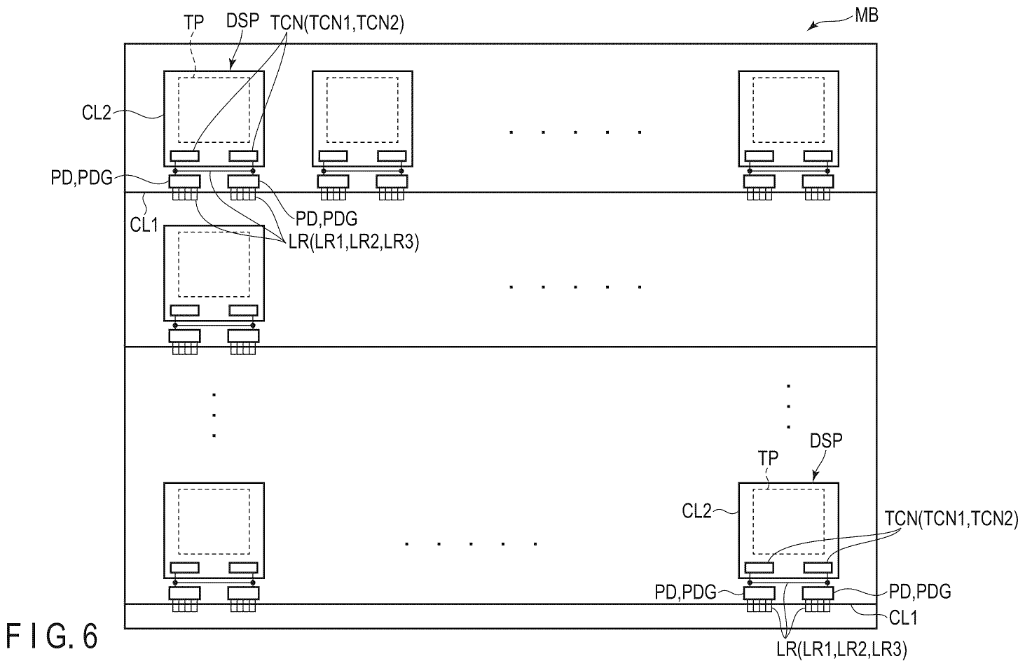

FIG. 6 is a plan view schematically showing a motherboard MB for display devices according to this embodiment. As shown in FIG. 6, on the motherboard MB for display devices, a plurality of display devices DSP with touch panels TP are arranged in a matrix.

The motherboard MB for display devices has such a configuration as shown in FIG. 5 for each display device DSP. In more detail, the motherboard MB for display devices comprises, for each display device DSP, inspection pads PD and ground pads PDG, high-resistance wiring lines LR1 and LR2 connecting the inspection pads PD and the ground pads PDG respectively to each other, and a first cut line CL1 set to cut out a plurality of display devices DSP from the motherboard MB for display devices, and a second cut line CL2 set along the outline shape of each single display device DSP. Note that the detailed illustration is omitted in FIG. 6, but the inspection pads PD each contain inspection pads corresponding respectively to a plurality of touch electrodes included in the touch panel TP. Further, the ground pad PDG includes two ground pads corresponding to the circular ground wiring lines included in the touch panel TP, and the two ground pads are connected by the high-resistance wiring line LR3, which is provided separately from the high-resistance wiring lines LR1 and LR2.

Note that at least the organic insulating layer is not disposed on the first cut line CL1 and the second cut line CL2. Although not shown in FIG. 6, verniers, marks or the like are provided near the first cut line CL1 and the second cut line CL2, respectively, to specify the positions of the first cut line CL1 and the second cut line CL2.

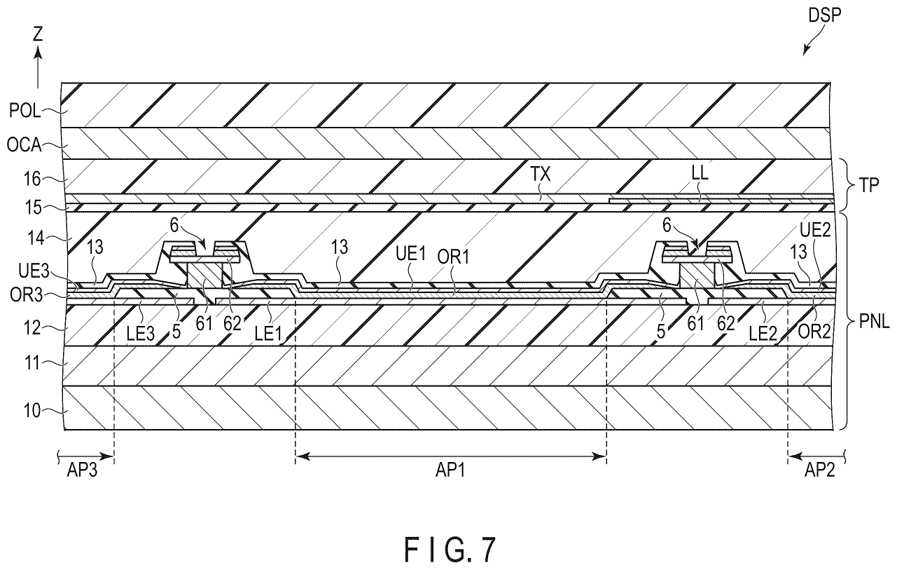

In the embodiment described above, such a configuration that the display panel PNL comprises one common electrode CE (upper electrode) over a plurality of pixels PX (subpixels SP) is described, but the configuration is not limited to this. For example, the display panel PNL may be configured to comprise an upper electrode for each subpixel SP, as shown in FIG. 7.

In this case, as shown in FIG. 7, in place of the bank BNK shown in FIG. 3, a partition 6 including a rib 5 having pixel apertures AP1, AP2, and AP3 and formed of an inorganic material, a conductive lower portion 61 disposed on the rib 5 and an upper portion 62 disposed on the lower portion 61 is disposed on the organic insulating layer 12. Note that the upper portion 62 has a width greater than that of the lower portion 61, and both end portions of the upper portion 62 protrude beyond the side surfaces of the lower portion 61. Such a shape of the partition 6 may be referred to as overhanging.

In the pixel apertures AP1, AP2, and AP3, the lower electrodes LE1, LE2, and LE3 are covered by organic layers OR1, OR2, and OR3, respectively, and the organic layers OR1, OR2, and OR3 are covered by upper electrodes UE1, UE2, and UE3, respectively. The upper electrodes UE1, UE2, and UE3 are each in contact with the side surfaces of the lower portion 61 of the partition 6.

Note that parts of the organic layers OR1, OR2, and OR3 and parts of the upper electrodes UE1, UE2, UE3 are located above the upper portion 62 of the partition 6. For example, parts of the organic layer OR3 and the upper electrode UE3 are located above the upper portion 62 of the partition 6, which is located on the left side of the figure, and are spaced apart from the organic layer OR3 and the upper electrode UE3 located below the partition 6. Similarly, parts of the organic layer OR2 and the upper electrode UE2 are located above the upper portion 62 of the partition 6, which is located on the right side of the figure, and are spaced apart from the organic layer OR2 and the upper electrode UE2 located below the partition 6. Further, parts of the organic layer OR1 and the upper electrode UE1 are located above the upper portion 62 of the partition 6 above the respective left and right sides of the figure, and are spaced apart from the organic layer OR1 and the upper electrode UE1 located below the partition 6.

The display panel PNL with such a configuration can as well be provided with a touch panel TP, as shown in FIG. 7. In this case as well, by using the configuration shown in FIG. 5 to perform the adjacent short-circuiting inspection and continuity inspection on the touch panel TP, it is possible to accurately detect adjacent short-circuiting in the touch panel TP and reduce the time and labor required for continuity inspection.

According to one embodiment described above, it is possible to provide a motherboard for display devices and a method of manufacturing a display device, that can improve the accuracy of the adjacent short-circuiting inspection.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A motherboard for display device, on which a plurality of display devices are formed, each comprising a display panel including a display area for displaying images and a touch panel including a plurality of touch electrodes overlapping the display area, the motherboard comprising:
a plurality of inspection pads each provided for each respective display device so as to inspect whether two touch electrodes adjacent to each other of the plurality of touch electrodes are short-circuited;
a first high-resistance wiring line connecting the plurality of inspection pads to each other;
a first cut line set to cut out a plurality of display devices from the motherboard for display device; and
a second cut line set along an outline shape of each single display device,
wherein
the plurality of inspection pads are each located between the first cut line and the second cut line and are electrically connected to the corresponding touch electrode for the inspection,
the first high-resistance wiring line is disposed across the first cut line and cut along the first cut line before the inspection using the plurality of inspection pads, and
the plurality of inspection pads are not connected to each other by the first high-resistance wiring line at the time of the inspection.

2. The motherboard of claim 1, wherein
the touch panel includes an annular ground wiring line,
the motherboard further comprises two ground pads electrically connected to the annular ground wiring line, and
the two ground pads are connected by a second high-resistance wiring line located between the first cut line and the second cut line.

3. The motherboard of claim 2, wherein
a resistance value of the second high-resistance wiring line is higher than a resistance value of the annular ground wiring line.

4. The motherboard of claim 3, wherein
in a continuity inspection of the annular ground wiring line, when the two ground pads are not brought into contact with a probe used for the continuity inspection, an infinite resistance value is detected as a result of the continuity inspection,
when the annular ground wiring line is disconnected, a resistance value of the second high- resistance wiring line is detected as a result of the continuity inspection, and
when the annular ground wiring line is not disconnected, a combined resistance value of the resistance value of the annular ground wiring line and the resistance value of the second high-resistance wiring line is detected as a result of the continuity inspection.

5. The motherboard of claim 1, wherein
at least an organic insulating layer is not disposed on the first cut line and the second cut line.

6. The motherboard of claim 5, wherein
the display panel includes:
a lower electrode;
a bank formed of an organic material, including a pixel aperture overlapping the lower electrode and covering a peripheral edge of the lower electrode;
an upper electrode opposing the lower electrode and disposed over a plurality of pixels arranged in a matrix in the display area; and
an organic layer disposed between the lower electrode and the upper electrode and emitting light according to a potential difference between the lower electrode and the upper electrode.

7. The motherboard of claim 5, wherein
the display panel includes:
a lower electrode;
a rib formed of an inorganic material, including a pixel aperture overlapping the lower electrode and covering a peripheral edge of the lower electrode;
a partition disposed above the rib,
an upper electrode opposing the lower electrode; and
an organic layer disposed between the lower electrode and the upper electrode and emitting light according to a potential difference between the lower electrode and the upper electrode.

8. A method of manufacturing each single display device from a motherboard comprising a plurality of display devices formed thereon, each comprising a display panel including a display area for displaying images and a touch panel including a plurality of touch electrodes overlapping the display area, the motherboard comprising a first cut line, a second cut line, a plurality of inspection pads provided between the first cut line and the second cut line, each provided for each respective display device, and a first high-resistance wiring line connecting the plurality of inspection pads to each other,
the method comprising:
cutting out a plurality of display devices from the motherboard for display device by cutting the motherboard for display device along the first cut line set to cross the first high-resistance wiring line;
inspecting whether two touch electrodes adjacent to each other among the plurality of touch electrodes are short-circuited using the plurality of inspection pads; and
forming an outline shape of each single display device by cutting the plurality of display devices along the second cut line after the inspection.

9. The method of claim 8, wherein
the touch panel includes an annular ground wiring line,
the motherboard further comprises two ground pads electrically connected to the annular ground wiring line, and
the two ground pads are connected by a second high-resistance wiring line located between the first cut line and the second cut line.

10. The method of claim 9, further comprising:
performing a continuity inspection of the annular ground wiring line by bringing probes into contact with the two ground pads before the cutting of the plurality of display devices along the second cut line.
